(19) United States
(12) Patent Application Publication
(10) Pub. No.: US 2015/0011269 A1
(43) Pub. Date: Jan. 8, 2015

(54) PORTABLE ELECTRONIC DEVICE

(71) Applicant: HON HAI PRECISION INDUSTRY CO., LTD., New Taipei (TW)

(72) Inventor: PO-CHUN LIU, New Taipei (TW)

(73) Assignee: HON HAI PRECISION INDUSTRY CO., LTD., New Taipei (TW)

(21) Appl. No.: 14/261,673

(22) Filed: Apr. 25, 2014

(30) Foreign Application Priority Data
Jul. 8, 2013 (TW) 102124321

(51) Int. Cl. H05K 5/02; H04M 1/02

(52) U.S. Cl. CPC H05K 5/0234; H04M 1/0206
USPC 455/575.1

(57) ABSTRACT

A portable electronic device includes a main body and a stand member. A sliding slot is defined in the rear side of the main body. The stand member includes two ends slidably received in the sliding slot. When the stand member is in a natural state, the stand member is fully received in the sliding slot. When the two ends of the stand member are slid to a first open position, the stand member is in a first curved state, and the stand member at a first display angle supports the main body. When the two ends of the stand member are slid to a second open position, the stand member is in a second curved state different from the first curved state, and the stand member at a second display angle different from the first display angle supports the main body.

### FIELD

The present disclosure relates to a portable electronic device, and more particularly to a portable electronic device with a stand.

### BACKGROUND

A typical portable electronic device, e.g., a cell phone, includes a main body and a stand pivotably attached to a rear side of the main body. When the stand is rotated to a slanting position relative to the main body, the stand can support the main body for facilitating users to watch images displayed by the portable electronic device.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of a first embodiment of a portable electronic device, showing a stand of the portable electronic device in a retracted position.

FIG. 2 shows the stand of the portable electronic device in a first open position.

FIG. 3 shows the stand of the portable electronic device in a second open position.

FIG. 4 is an exploded, section view of the portable electronic device of FIG. 1.

FIG. 5 is a side view of the portable electronic device of FIG. 2, showing the stand in the first open position.

FIG. 6 is a side view of the portable electronic device of FIG. 3, showing the stand in the second open position.

FIG. 7 shows the stand of the portable electronic device in a third open position.

FIG. 8 is a perspective view of a second embodiment of a portable electronic device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

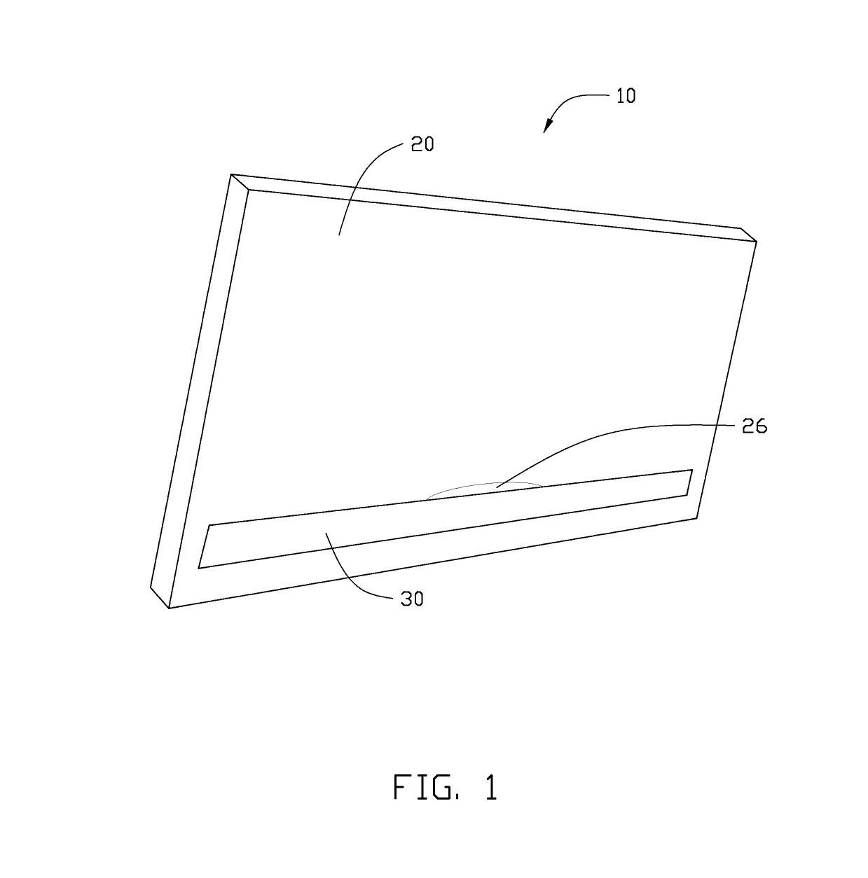

FIGS. 1 to 3 illustrate an embodiment of a portable electronic device 10. The portable electronic device 10 can comprise a main body 20 and a stand member 30 attached to a rear side of the main body 20. The portable electronic device 10 can include a display screen located at a front side of the main body 20. The stand member 30 can be a resilient, flexible piece.

A sliding slot 22 can be defined in the rear side of the main body 20 for mounting the stand member 30. The main body 20 can have a rectangular shape. The sliding slot 22 is substantially parallel and located adjacent to a long edge of the main body 20. A length of the sliding slot 22 is less than that of the main body 20. When the stand member 30 is in a natural state, a shape and size of the stand member 30 is the same as that of the sliding slot 22. An arc-shaped groove 26 is defined in the rear side of the main body 20 and can be coupled to a central portion of a long edge of the sliding slot 22 for facilitating the operation of the stand member 30.

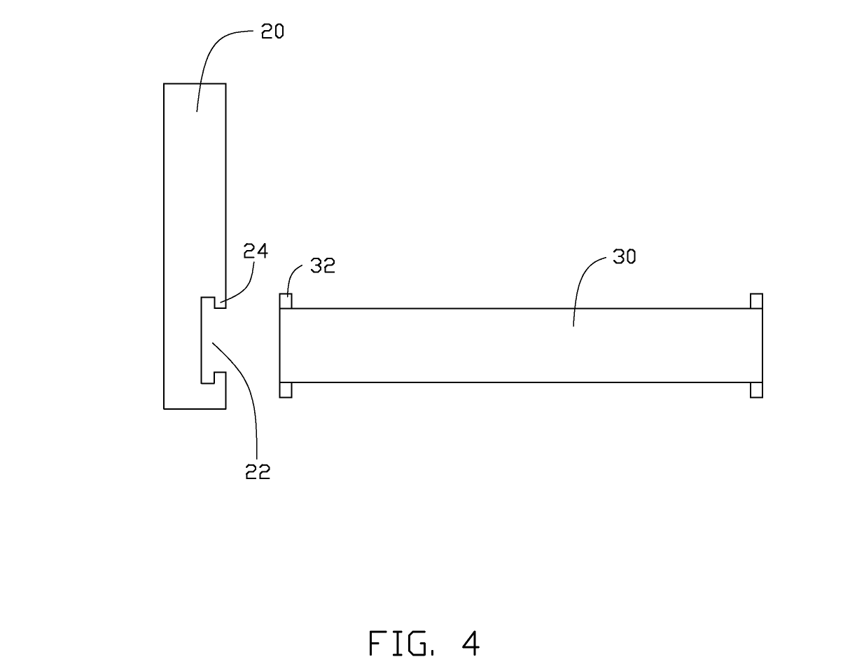

FIG. 4 shows that the stand member 30 can comprise two pairs of posts 32 that can be slidably mounted in the sliding slot 22. The two pairs of posts 32 can protrude from opposite long sides of the stand member 30 and can be located at four corners of the stand member 30. A pair of blocking flanges 24 can extend from opposite long edges of the sliding slot 22 corresponding to the two pairs of posts 32. When the stand member 30 is slidably mounted in the sliding slot 22, the two pairs of posts 32 can be located behind the pair of blocking flanges 24, thereby preventing the stand member 30 from disengaging away from the main body 20 along a first direction that is substantially perpendicular to a rear surface of the main body 20. Each post 32 can slide along the sliding slot 22 along a second direction that is substantially parallel to the long edge of the main body 20. When the post 32 is slid along the sliding slot 22, the post 32 can be rotated in the sliding slot 22 about an axis that is substantially perpendicular to the first direction and the second direction.

FIG. 1 illustrates that when the stand member 30 is in a retracted position, the stand member 30 is in a natural state and fully received in the sliding slot 22. The stand member 30 has an outer surface substantially flush with the rear surface of main body 20.

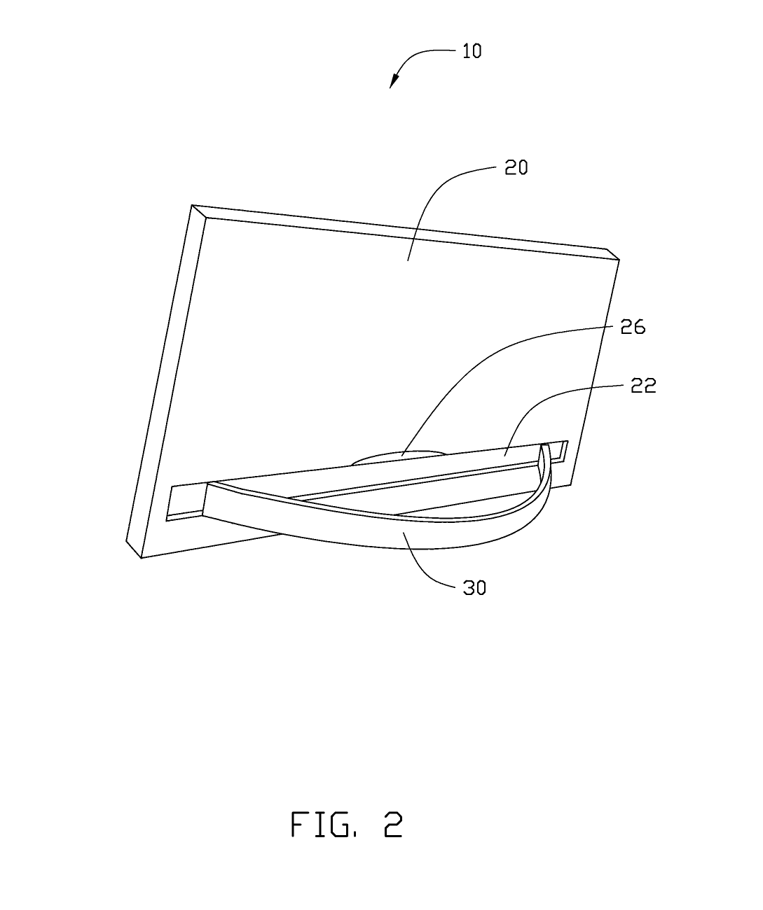

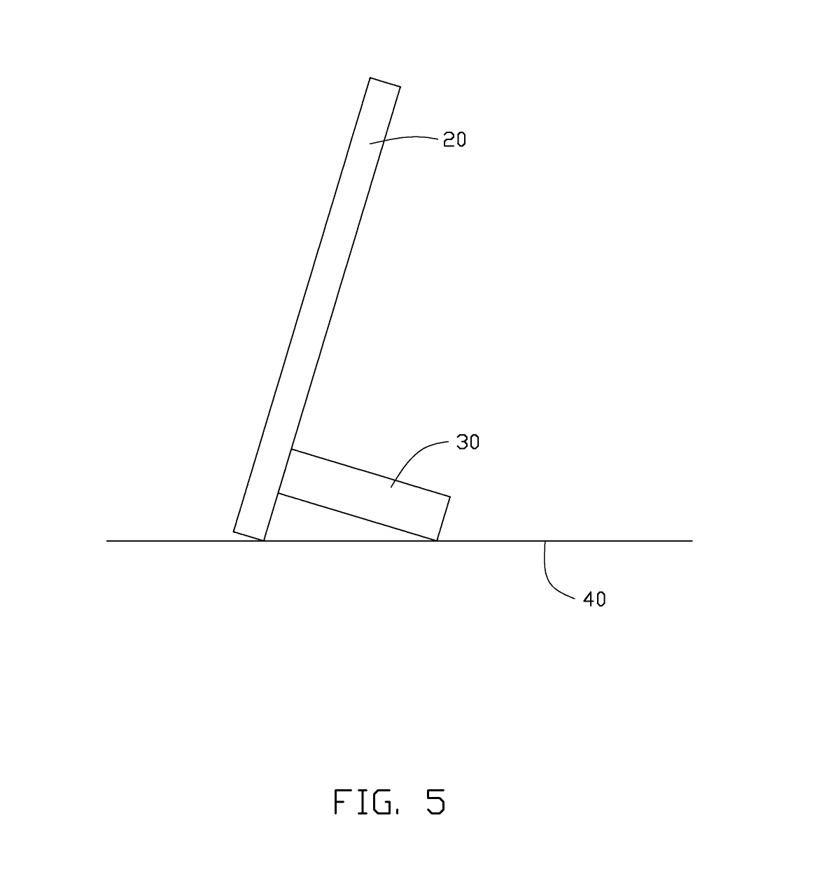

FIGS. 2 and 5 illustrate the stand member 20 pulled out from the retracted portion to a first open position. Two ends of the stand member 30 are slid from distal ends of the sliding slot 22 towards a central portion of the sliding slot 22. The stand member 30 is curved and in a first deformed state. The stand member 30 has a first curvature. The stand member 30 protrudes from the rear surface of the main body 20 and helps the portable electronic device 10 to stand on a horizontal plane 40 (see FIG. 5). A first angle is formed between the rear surface of the main body 20 and the horizontal plane 40.

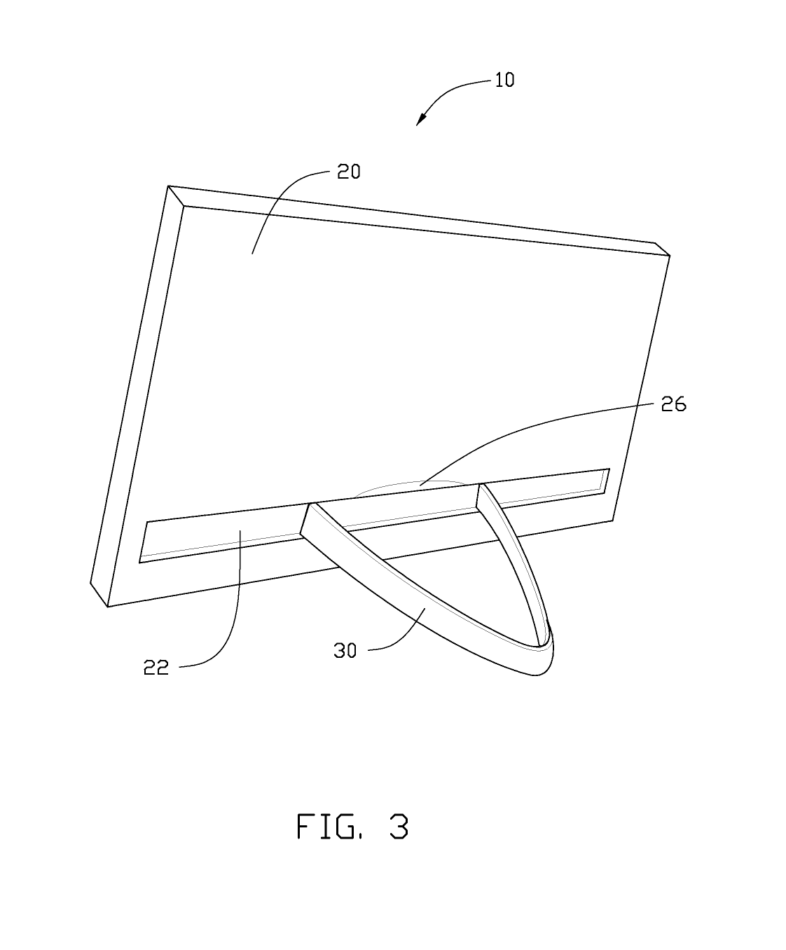

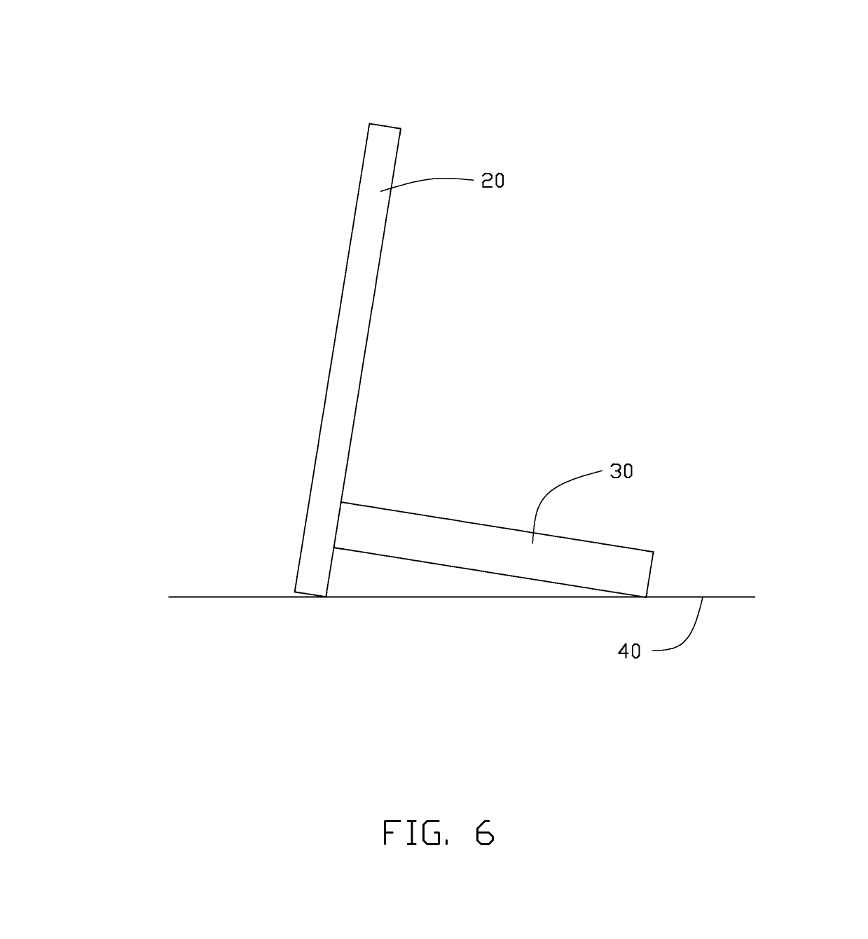

FIGS. 3 and 6 illustrate the stand member 30 pulled from the first open portion to a second open position. Two ends of the stand member 30 are slid along the sliding slot 22 and can become closer to each other. The stand member 30 is changed from the first deformed state to a second deformed state that is greater than the first deformed state. The stand member 30 helps the portable electronic device 10 to stand on the horizontal plane 40. A second angle can be formed between the rear surface of the main body 20 and the horizontal plane 40. The first angle and the second angle can be each less than 90 degrees. The second angle is greater than the first angle. The stand member 30 has a second curvature that is greater than the first curvature.

When the stand member 30 is in the first open position or the second open position, a symmetric line of the stand member 30 is substantially perpendicular to the rear surface of the main body 20. A vertex of the stand member 30 and a central point of the sliding slot 22 are in the symmetric line of the stand member 30.

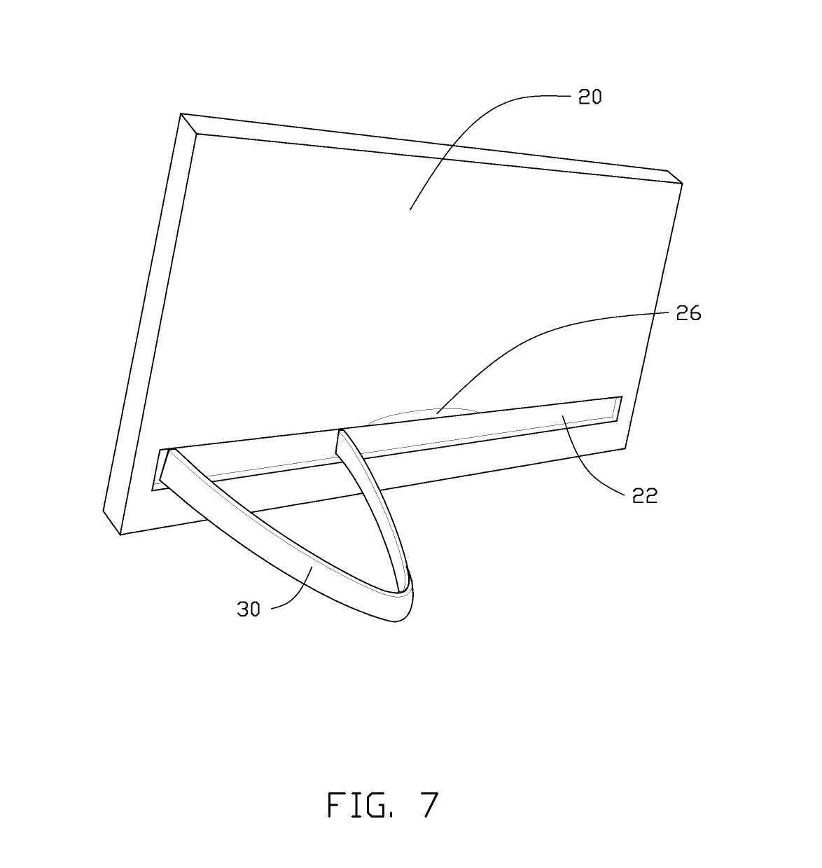

FIG. 7 illustrates the stand member 30 is in a third open position, wherein the stand member is curved and can be slid to one end of the sliding slot 22. The symmetric line of the stand member 30 can be deviated from the central position of the sliding slot 22. The stand member 30 can also support the main body 20 in the third open position.

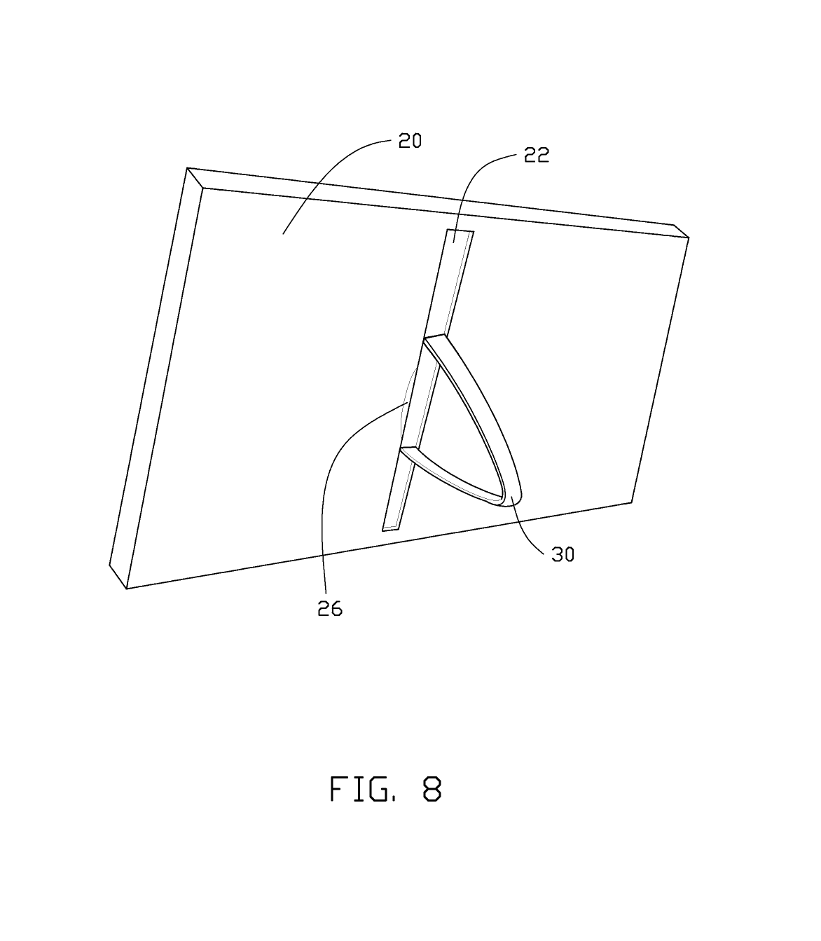

FIG. 8 illustrates that the sliding slot 22 can be defined in the rear side of the main body 22 and can extend along a vertical direction that is substantially perpendicular to the long edge of the main body 20. Two ends of the stand member 30 can slide along the sliding slot 22 along the vertical direction. When the stand member 30 is curved and protrudes from the rear side of the main body 20, the stand member 30 can support the portable electronic device 10.

In the above embodiments, when flexible curvatures of the stand member 30 varies, a display angle of the portable device will change.

It is to be understood, however, that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure. The disclosed embodiments are illustrative only, and are not intended to limit the scope of the following claims.

What is claimed is:

1. A portable electronic device comprising:
a main body with a sliding slot defined in the rear side of the main body; and
a stand member comprising two ends slidably received in the sliding slot; and the stand member is made from resilient flexible material;
wherein when the stand member is flat and in a natural state, the stand member is fully received in the sliding slot; when the two ends of the stand member are slid along the sliding slot to a first open position, the stand member is in a first curved state, and the main body is supported by the stand member at a first display angle; and when the two ends of the stand member are slid along the sliding slot to a second open position, the stand member is in a second curved state that is different from the first curved state, and the main body is supported by the stand member at a second display angle that is different from the first display angle.

2. The portable electronic device of claim 1, wherein when the two ends of the stand member are slid along the sliding slot, each of the two ends of the stand member is rotatable in the slot.

3. The portable electronic device of claim 2, wherein two pairs of posts protrude from opposite long sides of the stand member and located at four corners of the stand member, each post is slidably mounted in the slot.

4. The portable electronic device of claim 3, wherein a pair of blocking flanges extends from opposite long edges of the sliding slot for preventing the two pairs of posts from disengaging away from the sliding slot.

5. The portable electronic device of claim 1, wherein the main body has a rectangular shape, and the sliding slot is substantially parallel and located adjacent to a long edge of the main body.

6. The portable electronic device of claim 5, wherein when the stand member is in the natural state, a shape and size of the stand member is the same as that of the sliding slot.

7. The portable electronic device of claim 1, wherein a groove is defined in the rear side of the main body and connected to a central portion of a long edge of the sliding slot for facilitating operating the stand member.

8. The portable electronic device of claim 1, wherein when the stand member is in the first open position, there is a first protruding distance between a vertex of the stand member and the rear side of the main body; when the stand member is in the second open position, there is a second protruding distance between the vertex of the stand member and the rear side of the main body; and the second protruding distance is greater than the first protruding distance.

9. The portable electronic device of claim 8, wherein when the stand member is in the first open position, a first angle is formed between the main body and a horizontal plane which supports the portable electronic device; and when the stand member is in the second open position, a second angle is formed between the main body and the horizontal and greater than the first angle.

10. The portable electronic device of claim 1, wherein the main body has a rectangular shape, and the sliding slot extends along a direction that is substantially perpendicular to a long edge of the main body.

11. A portable electronic device comprising:
a main body with a sliding slot extending along a first direction that is substantially parallel to a long edge of the main body, or extending along a second direction that is substantially perpendicular to the long edge of the main body; and
a stand member comprising two ends slidably received in the sliding slot; and the stand member is made from resilient flexible material;
wherein when the stand member is a natural state, the stand member is fully received in the sliding slot; when the two ends of the stand member are slid along the sliding slot to a first open position, the stand member is in a first curved state, and the main body is supported by the stand member at a first display angle; and when the two ends of the stand member are slid along the sliding slot to a second open position, the stand member is in a second curved state that is different from the first curved state, and the main body is supported by the stand member at a second display angle that is different from the first display angle.

12. The portable electronic device of claim 11, wherein when the two ends of the stand member are slid along the sliding slot, each of the two ends of the stand member is rotatable in the slot.

13. The portable electronic device of claim 12, wherein two pairs of posts protrude from opposite long sides of the stand member and located at four corners of the stand member, each post is slidably mounted in the slot.

14. The portable electronic device of claim 13, wherein a pair of blocking flanges extends from opposite long edges of the sliding slot for preventing the two pairs of posts from disengaging away from the sliding slot.

15. The portable electronic device of claim 11, wherein when the stand member is in the natural state, a shape and size of the stand member is the same as that of the sliding slot.

16. The portable electronic device of claim 11, wherein a groove is defined in the main body and connected to a central portion of a long edge of the sliding slot for facilitating operating the stand member.

17. The portable electronic device of claim 11, wherein when the stand member is in the first open position, there is a first protruding distance between a vertex of the stand member and the main body; when the stand member is in the second open position, there is a second protruding distance between the vertex of the stand member and the main body; and the second protruding distance is greater than the first protruding distance.

18. The portable electronic device of claim 17, wherein when the stand member is in the first open position, a first angle is formed between the main body and a horizontal plane which supports the portable electronic device; and when the stand member is in the second open position, a second angle is formed between the main body and the horizontal and greater than the first angle.

19. The portable electronic device of claim 11, wherein when the stand member is in the first open position or in the second open position, two ends of the sliding slot is symmetrical to each other about a symmetric line of the stand member.

20. The portable electronic device of claim 11, wherein when the stand member is slid to a third open position, the stand member is curved and slid to one end of the sliding slot.
